(19) United States
(12) Patent Application Publication
(10) Pub. No.: US 2005/0217560 A1
(43) Pub. Date: Oct. 6, 2005

(54) Semiconductor wafers with non-standard crystal orientations and methods of manufacturing the same

(76) Inventors: Peter G. Tolchinsky, Beaverton, OR (US); Mohamad A. Shaheen, Portland, OR (US); Irwin Yablok, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/815,427

(22) Filed: Mar. 31, 2004

(51) Int. Cl. C30B 1/00; C30B 23/00; C30B 25/00; C30B 28/12; C30B 28/14

(52) U.S. Cl. 117/11

(57) ABSTRACT

The crystal orientations of monocrystalline semiconductor wafers may be varied by four parameters. The first parameter is the type of crystal seed used to grow the monocrystalline semiconductor ingot from which the wafers are cut. The second parameter is the angle at which the wafer is sliced from the ingot. The third parameter is the crystal plane towards which the wafer is cut. And, the fourth parameter is the position of the orientation indication feature that is used to align the wafer during processing. Different combinations of these parameters provide variations of non-standard crystal orientations of monocrystalline semiconductor wafers and semiconductor-on-insulator substrates such as silicon-on-insulator.

### BACKGROUND OF THE INVENTION

1. Field of the Invention

The present invention relates to the field of semiconductor substrates for integrated circuits and more particularly to the field of silicon-on-insulator substrates.

2. Discussion of Related Art

The monocrystalline silicon wafers used to form integrated circuit substrates have a face centered cubic crystal lattice having [100], [110], and [111] crystal planes. The relationship that the [100], [110], and [111] crystal planes have to one another is illustrated in FIG 1a. FIG 1a illustrates a single unit 105 of the monocrystalline silicon lattice. The faces 115 of this single unit 105 of the lattice are each [100] crystal planes. The [110] crystal plane 125 is perpendicular to the top horizontal [100] crystal plane 115, and the [111] crystal plane 135 is at a diagonal to the top horizontal [100] crystal plane 115.

The monocrystalline silicon wafers used to form substrates for integrated circuits typically have a standard crystal orientation of [100], determined by the crystal plane forming the flat horizontal top surface of the wafer. This crystal orientation is determined by how the monocrystalline silicon ingots are grown, how the wafers are sliced from the ingots, and how the wafers are aligned. Monocrystalline silicon is typically grown by a Czochralski (CZ) crystal growth method. The CZ crystal growth method involves the crystalline solidification of atoms from a liquid phase at an interface. Basically, a thin cylindrical silicon crystal seed having a crystal orientation of [100], [110], or [111] in the crosswise direction of the seed is lowered into pure molten silicon and then withdrawn from the molten silicon at a controlled rate to form a larger cylindrical monocrystalline silicon ingot 140 illustrated in FIG. 1b. The ingot 140 has a crystal orientation that is the same as that of the seed crystal, and in this example the ingot 140 has a [100] crystal orientation. This ingot 140 is then sliced in many positions 160 at a 90 degree angle from the lengthwise axis 150 of the cylindrical ingot 140 to form wafers 170. The [100] crystal ingot 140 is sliced along the [100] crystal plane to form the wafers having the [100] crystal plane along the horizontal flat surface of the wafer.

A monocrystalline silicon wafer 170 sliced from the ingot 140 is illustrated in FIG. 1c. The wafer 170 is marked with an orientation indication feature, such as a notch 180 or a flat, at a position aligned with the crystal plane along which the devices, such as transistor channels, will be aligned. Field effect transistors (FET's) have typically been formed with their channels aligned along the [110] crystal plane. FET's with channels aligned along the [100] crystal plane have also been developed. For example, as illustrated in FIG. 1c, a wafer 170 that has been sliced along the [100] crystal plane may have the notch 180 aligned with the [110] crystal plane that is perpendicular to the [100] crystal plane. The purpose of the orientation indication feature is to ensure that the devices are oriented in the same direction along the crystal planes in each batch of the wafers and consistently within a single wafer.

The monocrystalline silicon wafers manufactured by the above methods may be used as pure silicon substrates or as silicon-on-insulator (SOI) substrates. A silicon-on-insulator substrate 105 is illustrated in FIG. 1d. The SOI substrate 105 has a device layer of monocrystalline silicon 107 separated from a bulk layer of monocrystalline silicon 120 by a silicon dioxide (“oxide”) layer 130. SOI substrates may be manufactured by the Separation by IMplantation of OXygen (SIMOX) method or by the bond and split method. In the SIMOX method of forming an SOI substrate, oxygen atoms are implanted at a high dose into a monocrystalline silicon substrate and annealed to form the buried oxide 130 within the substrate. In the SIMOX method the device layer 107 and the bulk silicon substrate 120 will have the same crystal orientation.

The second method of forming an SOI substrate is generally known as the bond and split method. In this method a first monocrystalline silicon wafer has a thin oxide grown on its surface that will later serve as the buried oxide 130 in the SOI substrate. This first wafer is then flipped over and bonded to the surface of a second monocrystalline silicon wafer in which a high stress zone has been formed by the implantation of a high dose of ions. The first wafer is then cleaved along the high stress zone, resulting in the SOI substrate 105 as illustrated in FIG. 1d. The first and second wafers used in the bond and split method are aligned along their notches.

Monocrystalline silicon is an anisotropic material, meaning that the properties of monocrystalline silicon change depending on the direction from which they are measured within the crystal lattice of silicon. This may be explained by the different atomic densities within each of the [100], [110], and [111] crystal planes that are illustrated in FIG. 1e. The atomic densities of the [100] crystal plane 145, the [110] crystal plane 155, and the [111] crystal plane 165 are illustrated in FIG. 1e. Examples of properties that change with the direction in silicon include the Young's Modulus (a measure of the strength of the material), the mobility of electrons (or holes), the etch rate, and the oxidation rate. For example, the Young's modulus is 1.3 e¹² dynes/cm² in the [100] crystal plane 115, 1.7 e¹² dynes/cm² in the [110] crystal plane 125, and 1.9 e¹² dynes/cm² in the [111] crystal plane. As another example, the mobility of electrons in the direction of the [100] crystal plane is known to be greater than in the [110] crystal plane of silicon, resulting in a current drivability in the [100] direction that is approximately 15% greater than the current drivability in the [110] direction. Therefore, the above methods of forming, slicing, and notching monocrystalline silicon wafers and of forming SOI substrates limit the crystal structure of the wafers to certain orientations and in turn limit the properties of the devices made with the monocrystalline silicon wafers.

### BRIEF DESCRIPTION OF THE DRAWINGS

FIG. 1a is an illustration of a three-dimensional view of the three standard crystal planes of a diamond cubic crystal lattice.

FIG. 1b is an illustration of three-dimensional view of a monocrystalline silicon ingot sliced into wafers.

FIG. 1c is an illustration of a three-dimensional view of a monocrystalline silicon wafer having a [100] crystal orientation and a notch at the [110] crystal plane.

FIG. 1d is an illustration of a side view of a SOI substrate.

FIG. 1e is an illustration of the atomic density of the [100], [110], and [111] crystal planes.

FIG. 2 is an illustration of a flow chart of the different embodiments of manufacturing semiconductor wafers to have non-standard crystal orientations.

FIGS. 3a- 3e are illustrations of silicon ingots sliced along different angles into wafers according to embodiments of the current invention.

FIGS. 4a and 4b illustrate forming a notch along different crystal planes according to an embodiment of the current invention.

FIGS. 5a- 5c are an illustration of the SIMOX method of forming an SOI substrate.

FIG. 6 is an illustration of the bond-and-split method of forming an SOI substrate.

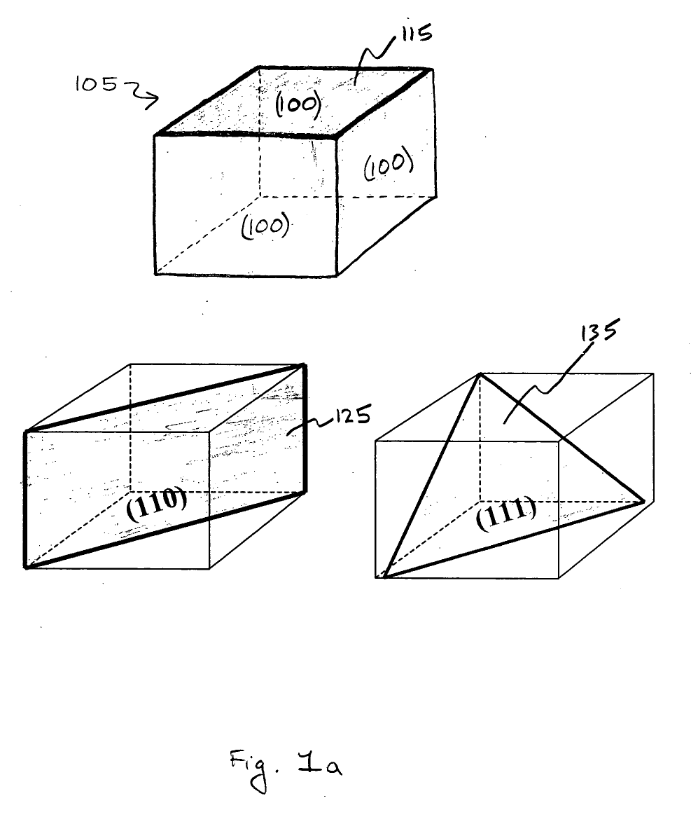

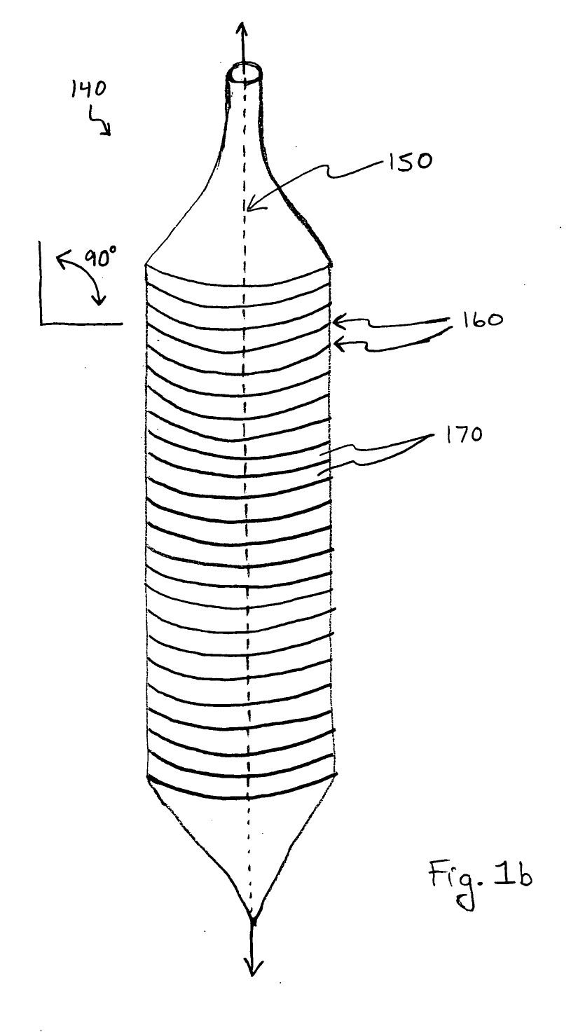

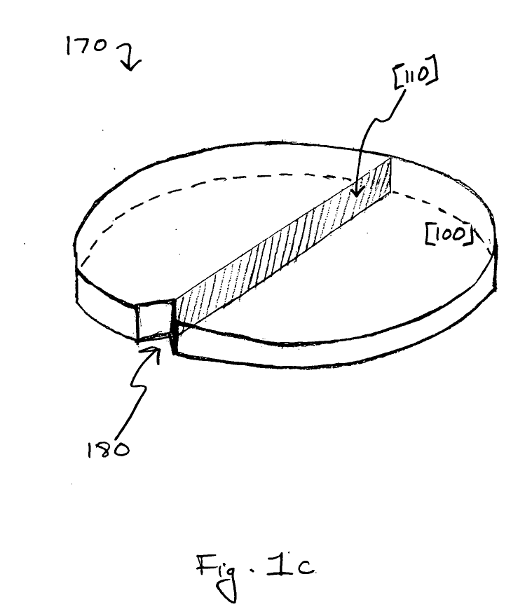

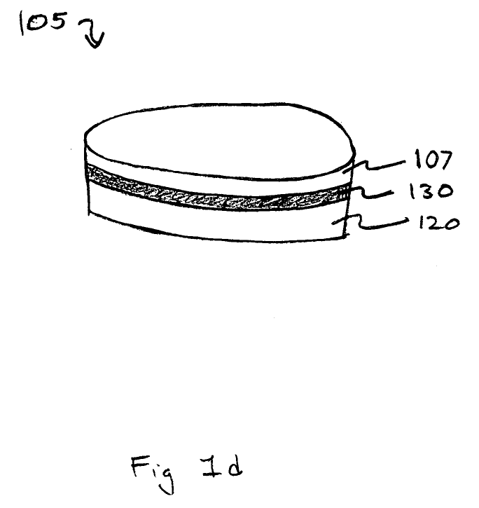

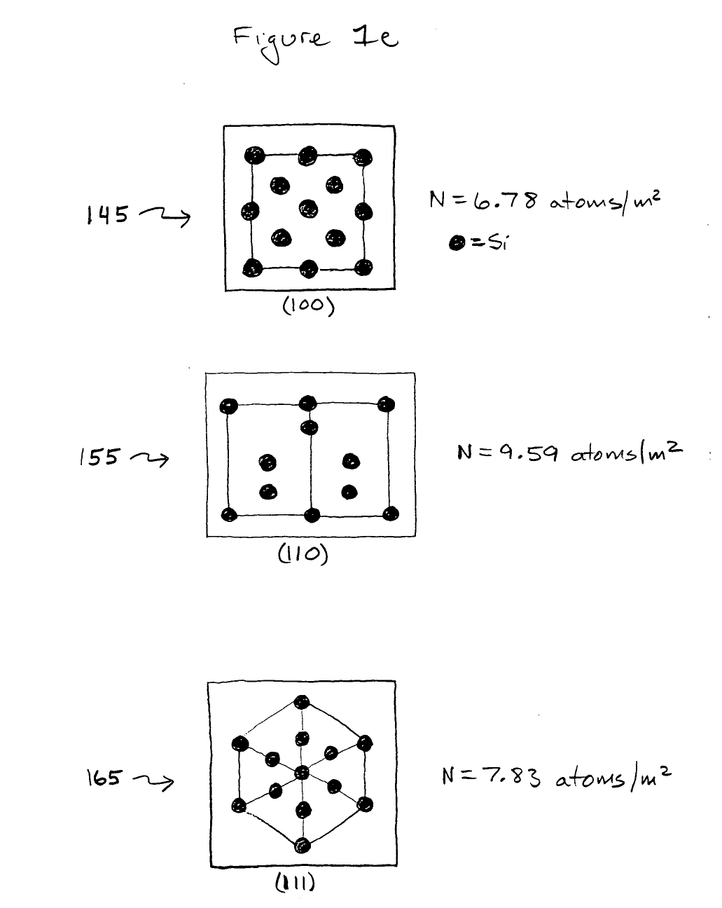

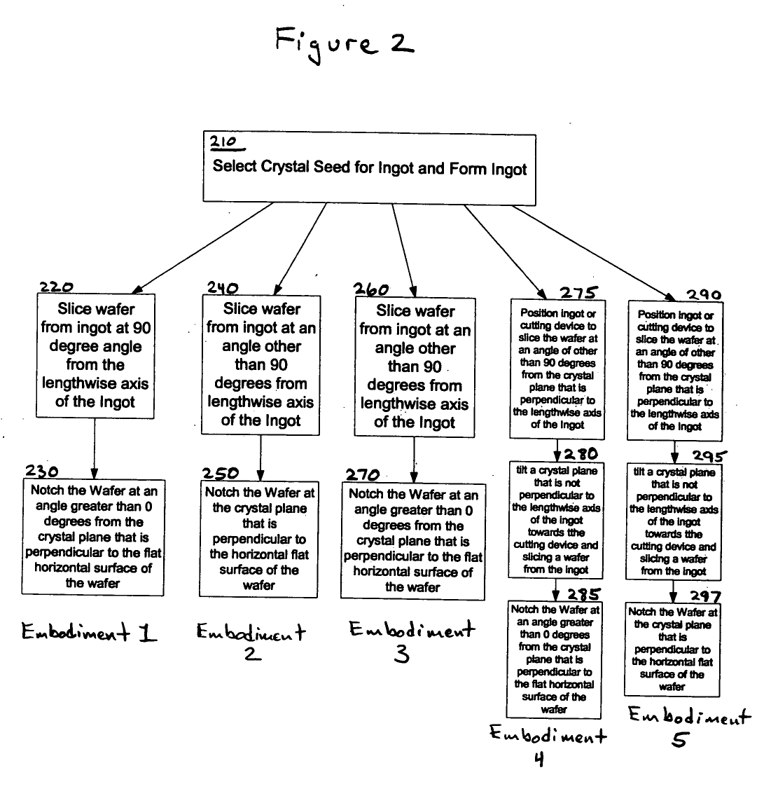

### DETAILED DESCRIPTION OF THE PRESENT INVENTION

Described herein are semiconductor wafers and semiconductor-on-insulator wafers having non-standard crystal orientations and methods of manufacturing the semiconductor wafers and the semiconductor-on-insulator substrates having non-standard crystal orientations. In the following description numerous specific details are set forth. One of ordinary skill in the art, however, will appreciate that these specific details are not necessary to practice embodiments of the invention. While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art. In other instances, well known semiconductor fabrication processes, techniques, materials, equipment, etc., have not been set forth in particular detail in order to not unnecessarily obscure embodiments of the present invention.

The properties of monocrystalline semiconductor substrates, such as silicon, germanium and gallium arsenide may be changed as the crystal orientation of the substrate is changed. These wafers having non-standard crystal orientations may form semiconductor substrates or they may be used to form semiconductor-on-insulator substrates such as silicon-on-insulator (SOI) substrates or germanium-on-insulator (GOI) substrates. The ability to change the properties of devices as the crystal orientation of the substrate is changed creates the ability to tailor the crystal orientation of the substrate to different devices or uses of the substrate.

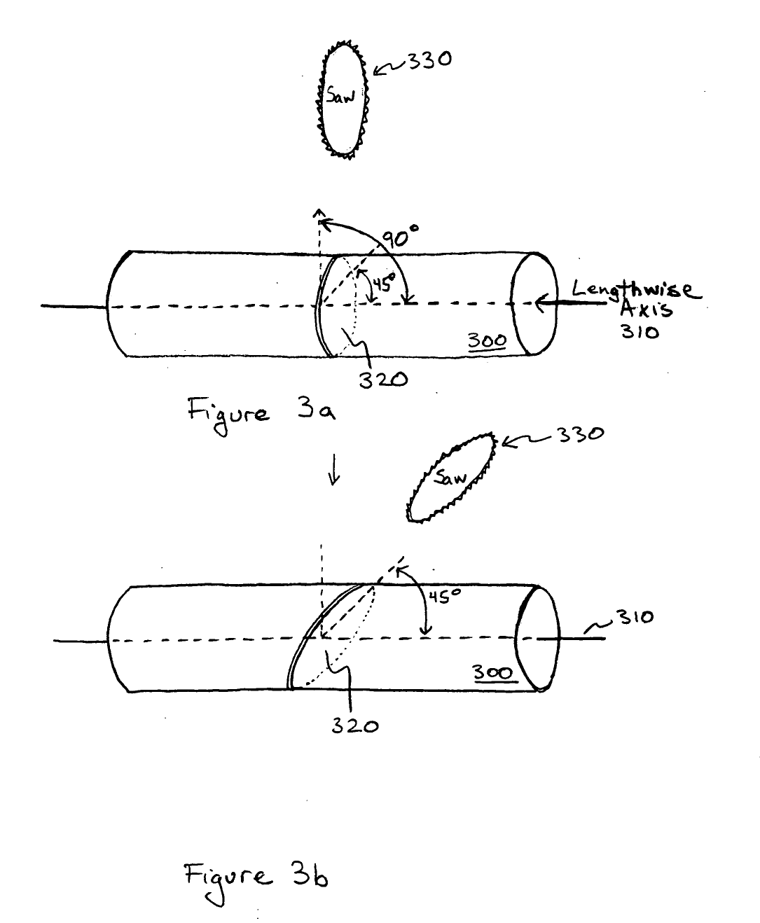

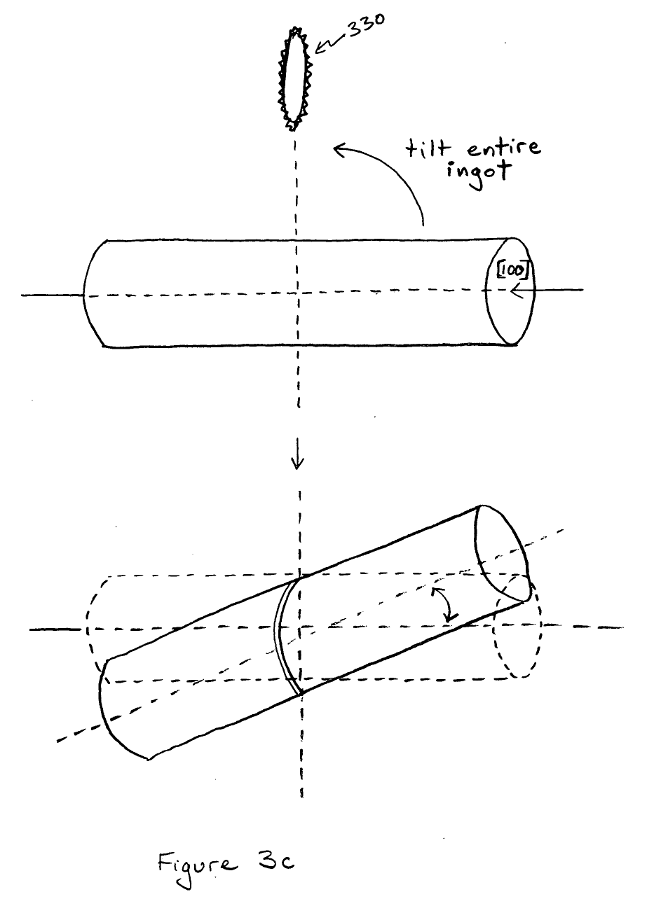

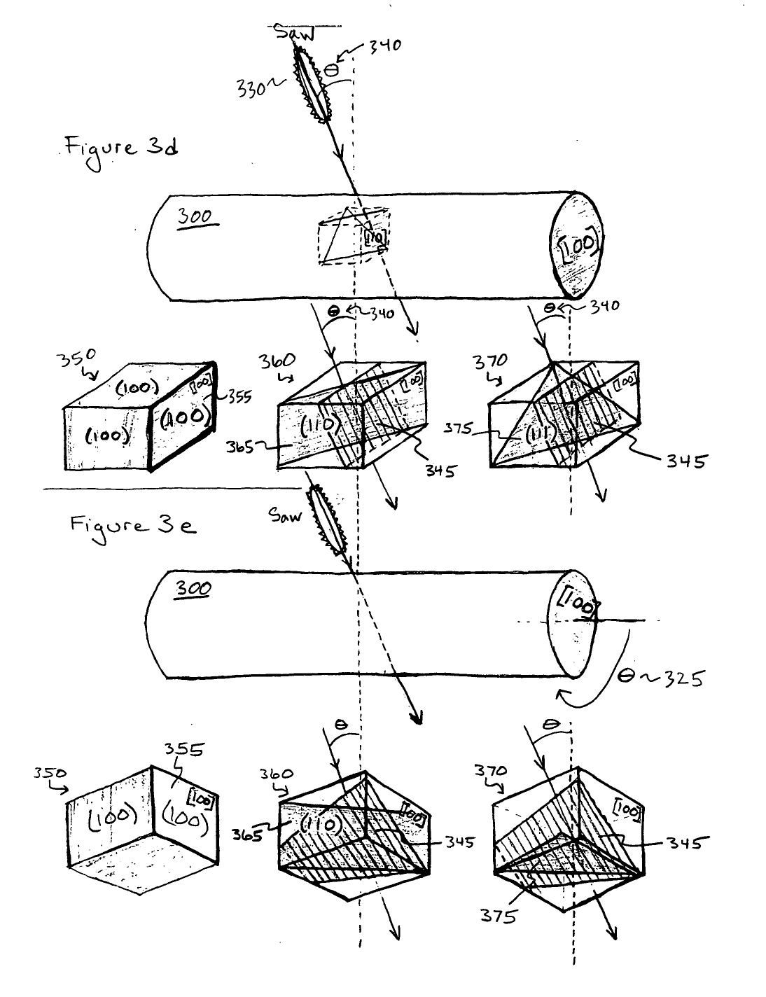

The crystal orientations of monocrystalline semiconductor wafers may be varied by four parameters. The first parameter is the type of crystal seed used to grow the monocrystalline semiconductor ingot from which the wafers are cut. The second parameter is the angle at which the wafer is sliced from the ingot. The third parameter is the crystal plane towards which the wafer is cut. And, the fourth parameter is the position of the orientation indication feature that is used to align the wafer during processing. Different combinations of these parameters provide variations of non-standard crystal orientations of the monocrystalline semiconductor wafers. FIG. 2 illustrates a flow chart of five embodiments by which the crystal orientation of the monocrystalline semiconductor substrate may be varied. At 210, in each of the five embodiments, the seed crystal for the ingot is selected to have a predetermined crystal orientation. In one particular embodiment, the seed crystal for semiconductors having a face centered cubic crystal lattice (such as silicon and germanium) is selected based on which crystal plane selected from [100], [110], and [111] is to be perpendicular to the lengthwise axis 310 of the ingot, illustrate in FIG. 3a. In this embodiment, if the ingot is sliced at a 90 degree angle to the lengthwise axis 310, the flat horizontal surface of the resulting wafer will be parallel to one of the crystal planes selected from [100], [110], and [111].

After selecting the seed crystal, an ingot is formed by the Czochralski (CZ) method. In the CZ method the seed crystal is placed in a solution of molten semiconductor material and then withdrawn at a controlled rate as a monocrystalline semiconductor ingot 300, illustrated in FIG. 3a, having a predetermined diameter in the approximate range of 100 mm and 450 mm. In one particular embodiment, the diameter of the ingot may be approximately 300 mm. The rate at which the ingot is withdrawn from the molten semiconductor material is determined by parameters such as diameter of the ingot, crystallization speed, temperature, and the type of material being crystallized. The ingot 300 is formed by the crystalline solidification of atoms from the liquid phase of the molten semiconductor material at the interface of the seed crystal and the molten semiconductor material. The ingot 300 has the same crystal orientation as the seed crystal.

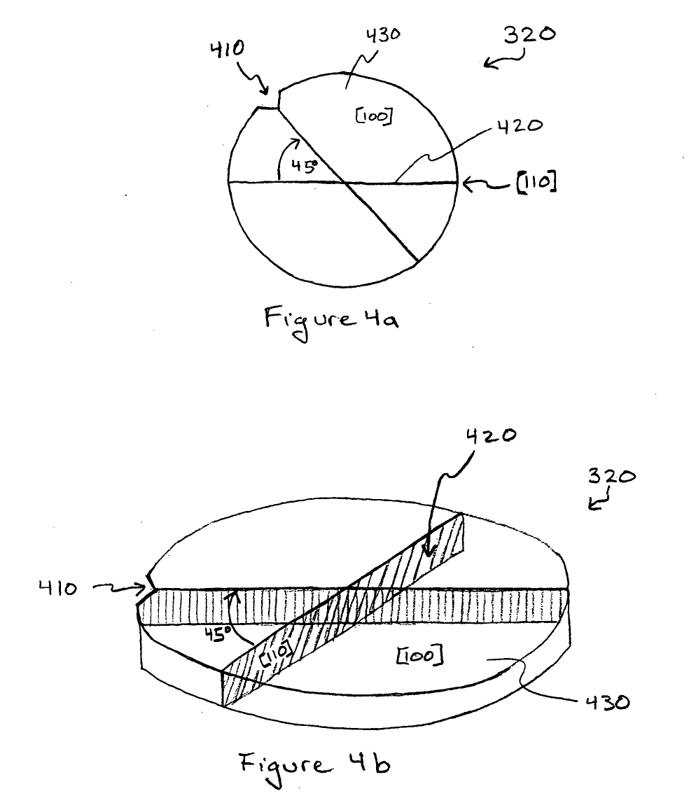

After the monocrystalline semiconductor ingot 300 has been formed to have a particular crystal orientation, in a first embodiment of forming a semiconductor substrate having a non-standard crystal orientation at 220, the ingot 300 is sliced crosswise at approximately a 90 degree angle from the lengthwise axis 310 of the ingot 300, as illustrated in FIG. 3a, to form the wafer 320. Many wafers 320 may be sliced from the ingot 300, each having a thickness in the approximate range from 375 microns to 800 microns, depending on the diameter of the wafer. For a wafer having a diameter of approximately 300 mm the thickness of the wafer may be in the approximate range of 750 microns to 800 microns. At 230, after slicing the wafer 320 from the ingot 300, the wafer 320 is marked at a position to form an orientation indication feature, such as a notch or a flat, that is at an angle of greater than 0 degrees from a crystal plane perpendicular to the horizontal surface of the wafer. FIG. 4a illustrates a particular embodiment where the notch 410 is positioned at a 45 degree angle from the [110] crystal plane 420 perpendicular to the [100] crystal plane parallel to the flat horizontal surface 430 of the silicon wafer 320.

At 240, in the second embodiment of forming a semiconductor substrate having a non-standard crystal orientation, the ingot 300 may be sliced at an angle other than 90 degrees from the lengthwise axis 310 of the ingot. As illustrated in FIG. 3b, the ingot 300 may be sliced at an angle by angling the cutting device 330 relative to the ingot 300 while the ingot 300 is mounted in a standard position. Alternatively, this ingot may be cut at an angle other than 90 degrees from the lengthwise axis 310 of the ingot 300 by keeping the cutting device 330 that is used to cut the ingot 300 in the standard position and angling the mounting position of the ingot 300 prior to slicing, as illustrated in FIG. 3c. As illustrated in FIG. 3b, for example, the ingot may be sliced at an angle of 45 degrees from the lengthwise axis 310. In a particular embodiment, the ingot may be sliced at an angle in the approximate range of 0.01 degrees and 10 degrees to maintain the roundness of the wafer.

At 250, after slicing the wafer 320 from the ingot 300, an orientation indication feature is formed in the wafer 320 at a position aligned with a crystal plane that is perpendicular to the flat horizontal surface of the wafer. In a particular embodiment, the orientation indication feature may be formed at the [110] crystal plane 420 that is perpendicular to a [100] crystal plane parallel to the flat horizontal surface 430 of a monocrystalline silicon wafer 320.

At 260, in the third embodiment of forming a semiconductor substrate having a non-standard crystal orientation at 260, the ingot 300 may be sliced at an angle other than 90 degrees from the lengthwise axis 310 of the ingot, as described above. Then, at 270, the wafer 320 may be marked at a position to form an orientation indication feature that is at an angle of greater than 0 degrees from a crystal plane perpendicular to the horizontal surface of the wafer, also as described above.

The fourth embodiment of forming a semiconductor substrate having a non-standard crystal orientation further refines the position at which the wafer is sliced. At 275 the ingot 300 or the cutting device 330 is positioned to slice the wafer at an angle of other than 90 degrees from the first crystal plane that is perpendicular to the lengthwise axis of the ingot 300, as illustrated in FIG. 3d. FIG. 3d illustrates a particular embodiment where the first crystal plane is a [100] crystal plane and the cutting device 330 is positioned at an angle 340 to the ingot 300. The orientation of the crystal planes of the ingot 300 relative to the cutting device 330 are illustrated by single cubes of the face centered cubic crystal lattice 350, 360, and 370. The cube 350 illustrates the [100] crystal plane 355 that is at an angle 340 to the cutting device 330. The [110] crystal plane 365 is illustrated by cube 360 where 345 illustrates the cutting plane along which the cutting device 330 would cut relative to the [110] crystal plane 365. The [111] crystal plane 375 is illustrated by cube 370 where 345 illustrates the cutting plane along which the cutting device 330 would cut relative to the [111] crystal plane. At block 280 and in FIG. 3e, the ingot 300 has been rotated by an angle 325 to tilt a crystal plane that is not perpendicular to the lengthwise axis of the ingot towards the cutting device 330. The angle 325 by which the crystal plane is tilted towards the cutting device 330 may be any angle greater than zero degrees. In the embodiment illustrated in FIG. 3e, the [110] crystal plane has been tilted towards the cutting device 330. The cutting plane 345 cuts through the [110] crystal plane 365 at a different position in FIG. 3e than in FIG. 3d due to the tilting of the [110] crystal plane towards the cutting device 330. Tilting the [110] crystal plane towards the cutting device 330 also changes the positions at which the cutting plane 345 cuts through the [100] crystal plane 355 and the [111] crystal plane 375. In an alternate embodiment the [111] crystal plane may be tilted towards the cutting device 330 (not illustrated) to change the crystal orientation of the wafer cut from the ingot 300. At block 285 the wafer 320 may be marked at a position to form an orientation indication feature that is at an angle of greater than 0 degrees from a crystal plane perpendicular to the horizontal surface of the wafer, as described above.

At block 290, in the fifth embodiment of forming a semiconductor substrate having a non-standard crystal orientation, the ingot 300 may be positioned relative to the cutting device at an angle other than 90 degrees from a crystal plane perpendicular to the lengthwise axis of the ingot. At block 295, a crystal plane that is not perpendicular to the lengthwise axis of the ingot is tilted towards the cutting device 330. The wafer is then sliced in to a wafer 320, as described above. Then, at 297, the wafer 320 may be marked to form an orientation indication feature at a crystal plane that is perpendicular to the horizontal flat surface of the wafer, also as described above.

Forming a semiconductor wafer having a non-standard crystal orientation by any of the embodiments described above may change the properties of the wafer. The properties that may be changed include the etching rate and characteristics, the oxidation rate and characteristics, the hardness of wafer in a particular direction, and the mobility of electrons within the wafer in a particular direction.

After the monocrystalline semiconductor wafer 320 has been sliced and marked to form an orientation indication feature, such as a notch or a flat, by one of the above embodiments, the monocrystalline semiconductor wafer 320 may become a pure semiconductor substrate, or part of a semiconductor-on-insulator substrate. Devices formed on SOI substrates have lower power consumption and higher speed in most cases due to the improved isolation between devices on an semiconductor-on-insulator substrate. A semiconductor-on-insulator substrate may be formed by one of two general methods: (1) implanting the substrate with a material that will form an insulating layer within the substrate and (2) bonding a first wafer on which an insulating layer has been formed to a second wafer so that the insulating layer is sandwiched in between the two wafers.

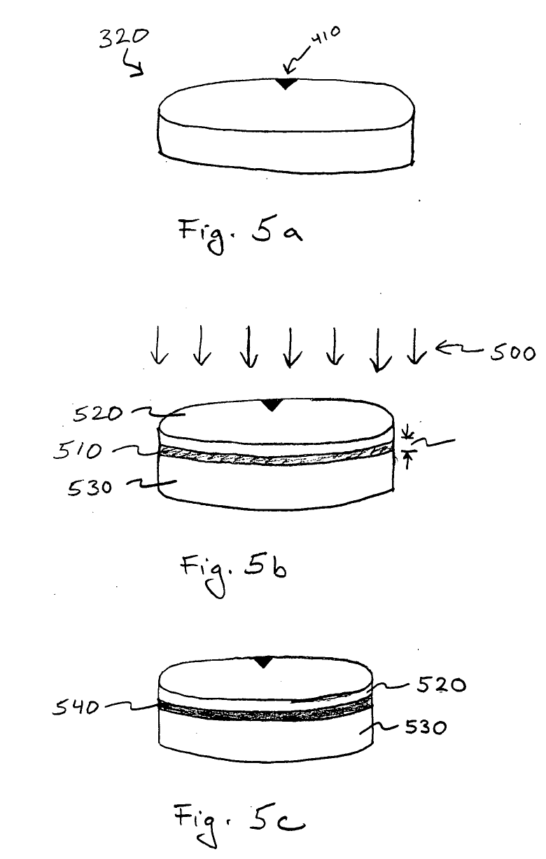

One particular embodiment of the method of implanting the substrate with a material that will form an insulating layer within the substrate is SIMOX, or Separation by IMplantation of Oxygen, where a buried oxide is formed within a semiconductor wafer by implanting oxygen. This method is illustrated in FIGS. 5a-5c. In FIG. 5a a wafer 320 is provided that has been sliced and marked to form an orientation indication feature by one of the above embodiments to determine the non-standard crystal orientation of the wafer 320. The non-standard crystal orientation of the wafer 320 may be chosen based on the types of devices that may be formed on the wafer. For example, if CMOS transistors are to be formed in the device layer of silicon, a non-standard crystal orientation having a high mobility of electrons or holes in the direction of the transistor channels may be used. In brief, after the ingot has been grown from a seed crystal to have a predetermined crystal orientation, five possible methods may be followed. These five method embodiments are: (1) slicing the ingot at an angle of 90 degrees from the lengthwise axis of the ingot to form a wafer and marking the wafer to form an orientation indication feature at a position that is at an angle greater than 0 degrees from a crystal plane perpendicular to the flat horizontal surface of the wafer, (2) slicing the ingot at an angle of other than 90 degrees from the lengthwise axis of the ingot to form a wafer and marking the wafer to form an orientation indication feature at a position that is aligned with a crystal plane that is perpendicular to the flat horizontal surface of the wafer, (3) slicing the ingot at an angle of other than 90 degrees from the lengthwise axis of the ingot to form a wafer and marking the wafer to form an orientation indication feature at a position that is at an angle greater than 0 degrees from a crystal plane perpendicular to the flat horizontal surface of the wafer, (4) slicing the ingot at an angle of other than 90 degrees from the lengthwise axis of the ingot where a crystal plane that is not perpendicular to the lengthwise axis of the ingot is tilted towards a cutting device and marking the wafer to form an orientation indication feature at a position that is at an angle greater than 0 degrees from a crystal plane perpendicular to the flat horizontal surface of the wafer, and (5) slicing the ingot at an angle of other than 90 degrees from the lengthwise axis of the ingot where a crystal plane that is not perpendicular to the lengthwise axis of the ingot is tilted towards a cutting device and marking the wafer to form an orientation indication feature at a position that is aligned with a crystal plane that is perpendicular to the flat horizontal surface of the wafer.

In FIG. 5b, the semiconductor wafer 320 is implanted with oxygen 500 to form an implant layer 510 within the monocrystalline silicon wafer 320 that separates the device layer 520 from the bulk silicon layer 530. In one embodiment, where the wafer 320 is a monocrystalline silicon wafer, the oxygen implant is accomplished by bringing the wafer 320 to a temperature in the approximate range of 400° C. and 600° C. upon which a dose of oxygen in the approximate range of 2e¹⁷/cm² and 2e¹⁸/cm² and at an implantation energy in the approximate range of 50 keV and 200 keV may be implanted into the wafer 320. In FIG. 5c, the monocrystalline silicon wafer 320 with the implanted oxygen region is then annealed in an inert or oxidizing ambient at a temperature of greater than 1300° C., but less than the silicon melting point of 1421° C., for at least five hours. The anneal forms a silicon dioxide insulator layer 540, or buried oxide, within the wafer 320 having a thickness in the approximate range of 100 A and 3000 A. The anneal also serves to repair defects in the semiconductor material that occurred during the oxygen implant. The wafer, in this particular embodiment is now a silicon-on-insulator (SOI) substrate having a semiconductor device layer 520, an insulator layer 540, and a bulk semiconductor layer 530. The thickness of the device layer of monocrystalline silicon depends on what types of devices are formed. A “thick” device layer having a thickness of approximately greater than 1.5 microns may be used for bipolar, MEM's (microelectronic machines), and plasma display technologies. A “thin” device layer having a thickness of less than 0.5 microns may be used for digital CMOS and memory and logic devices. In a particular embodiment where the devices to be formed are partially depleted or fully depleted CMOS transistors on 300 mm wafers the device layer may have a thickness in the approximate range of 50 A-1000 A and the bulk monocrystalline silicon layer may have a thickness in the approximate range of 775 um. The thickness of the bulk semiconductor layer may also be varied based on different applications, for example when MEM's are formed in the bulk layer. In alternate embodiments the semiconductor wafer 320 may be other semiconductor materials such as germanium and gallium arsenide and the material that is implanted may be nitrogen or any other material that will form a buried insulating layer within the wafer 320.

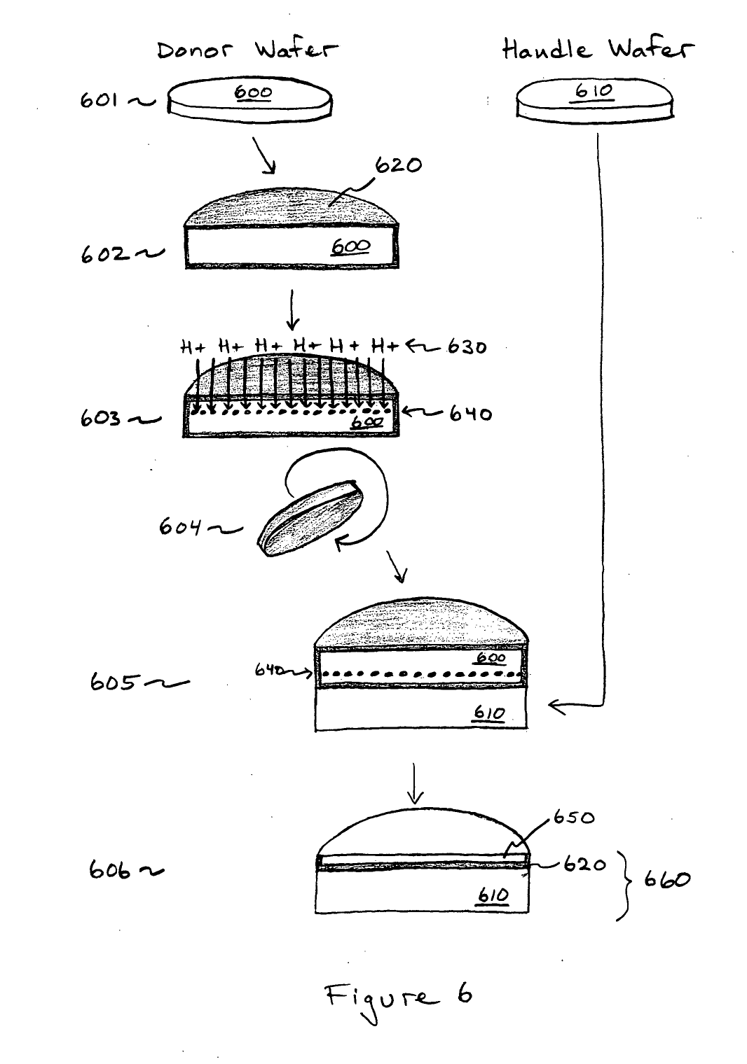

The SOI substrate may also be formed by the “bond-and-split” method, the “bond-and-grind” method, or the “bond-and-etch” method. In these methods, two wafers are bonded together and then a portion of one of the wafers is removed by splitting, grinding, or etching. Because these methods involve two wafers bonded to one another, in addition to varying the parameters of each wafer to affect the crystal orientation of the monocrystalline silicon substrate, the crystal orientations of the wafers may also be varied with respect to one another. FIG. 6 illustrates the “bond-and-split” method. In this method, two wafers, a donor wafer 600 and a handle wafer 610 are provided at 601. The crystal orientation of each of these wafers may be determined by any of the embodiments for forming a non-standard crystal orientation described above. In brief, after the ingot has been grown from a seed crystal to have a predetermined crystal orientation, five possible method embodiments may be followed. These five method embodiments are: (1) slicing the ingot at an angle of 90 degrees from the lengthwise axis of the ingot to form a wafer and marking the wafer to form an orientation indication feature at a position that is at an angle greater than 0 degrees from a crystal plane perpendicular to the flat horizontal surface of the wafer, (2) slicing the ingot at an angle of other than 90 degrees from the lengthwise axis of the ingot to form a wafer and marking the wafer to form an orientation indication feature at a position that is aligned with a crystal plane that is perpendicular to the flat horizontal surface of the wafer, (3) slicing the ingot at an angle of other than 90 degrees from the lengthwise axis of the ingot to form a wafer and marking the wafer to form an orientation indication feature at a position that is at an angle greater than 0 degrees from a crystal plane perpendicular to the flat horizontal surface of the wafer, (4) slicing the ingot at an angle of other than 90 degrees from the lengthwise axis of the ingot where a crystal plane that is not perpendicular to the lengthwise axis of the ingot is tilted towards a cutting device and marking the wafer to form an orientation indication feature at a position that is at an angle greater than 0 degrees from a crystal plane perpendicular to the flat horizontal surface of the wafer, and (5) slicing the ingot at an angle of other than 90 degrees from the lengthwise axis of the ingot where a crystal plane that is not perpendicular to the lengthwise axis of the ingot is tilted towards a cutting device and marking the wafer to form an orientation indication feature at a position that is aligned with a crystal plane that is perpendicular to the flat horizontal surface of the wafer.

In an alternate embodiment, only one of the two wafers, the handle wafer 610 or the donor wafer 600, may have a non-standard crystal orientation determined by one of the three embodiments of forming a non-standard crystal orientation described above, while the other wafer has a standard crystal orientation ([100], [110], or [111].) In another embodiment, the wafers may both have standard crystal orientations, but the orientation indication feature of one wafer may be positioned at an angle greater than 0 degrees from a crystal plane perpendicular to the flat horizontal surface of the wafer so that the crystal planes of the two wafers are not aligned. In another embodiment, the handle wafer 610 may not be a monocrystalline semiconductor substrate, but instead may be a material such as sapphire or a heat dissipation substrate such as silicon carbide. In yet another embodiment, the donor wafer 600 and the handle wafer 610 may be different types of monocrystalline semiconductor substrates, such as, for example, where the donor wafer 600 is silicon and the handle wafer is germanium.

At 602 the donor wafer 600 undergoes thermal oxidation to form a silicon oxide layer 620 over the surface of the donor wafer 600. The thickness of the thermal oxide may be in the approximate range of 100 A to 100 microns. At 603 the donor wafer 600 is implanted with ions 630, which in this particular example are hydrogen ions, to form a stress zone 640 along which the donor wafer 600 will be split. The depth of the stress zone 640 depends on the thickness of the device layer 520 of the complete SOI substrate. Next, at 604, the donor wafer 600 is flipped over so that the stress zone 640 is in close proximity to the handle wafer 610 when the donor wafer 600 is bonded to the handle wafer 610 at 605. The donor wafer 600 forms weak chemical bonds to the handle wafer 610 by Van der Walls forces between the silicon atoms of each wafer. The donor wafer 600 and the handle wafer 610 are then heated at a temperature in the approximate range of 100° C. to 600° C. for a time in the approximate range of 1 to 30 minutes to form strong covalent bonds between the two wafers. During the heating of the wafers to bond the handle wafer 610 to the donor wafer 600, tiny air blisters form along the stress zone 640.

At 606 the donor wafer 600 is split along the stress zone 640 along the air blisters to form the SOI substrate 660 having a device layer 650, an insulating silicon dioxide layer 620, and a bulk layer 610 formed from the handle wafer. In an alternate embodiment the ion implantation at 603 may be skipped, and after bonding the donor wafer 600 to the handle wafer 610, the donor wafer may be chemically etched back using for example, conventional acid or caustic etch solutions. The donor wafer may also be mechanically ground back to form the device layer 650.

The bond and split, bond and etch-back, and bond and grind-back methods offer great flexibility in forming SOI wafers because two wafers of the same or different material or of the same or different crystal orientations can be bonded to one another. The crystal orientation of the device layer may therefore be changed in relation to the handle wafer. The variability may be valuable in instances where a thin device layer is used in combination with a mechanically strong silicon carbide handle wafer or where transistors are formed on the device layer and MEM's are formed on the handle wafer.

Several embodiments of the invention have thus been described. However, those of ordinary skill in the art will recognize that the invention is not limited to the embodiments described, but can be practiced with modification and alteration within the scope and spirit of the appended claims that follow.

1. A method, comprising:
forming a monocrystalline semiconductor ingot from a crystal seed having a predetermined crystal orientation, the monocrystalline semiconductor ingot having a lengthwise axis; and
slicing the monocrystalline semiconductor ingot at an angle other than 90 degrees to the lengthwise axis to form a wafer.

2. The method of claim 1, further comprising forming the monocrystalline semiconductor ingot from the crystal seed having the predetermined crystal orientation selected from the group consisting of a [100], [110], or [111] crystal plane perpendicular to the lengthwise axis of the ingot.

3. The method of claim 2, wherein slicing the monocrystalline semiconductor ingot at an angle other than 90 degrees to the lengthwise axis further comprises tilting the ingot towards a crystal plane that is not perpendicular to the lengthwise axis of the ingot before slicing the ingot to form a wafer.

4. The method of claim 1, further comprising notching the wafer to form an orientation indication feature at an angle greater than 0 degrees from a crystal plane that is perpendicular to a horizontal surface of the wafer.

5. The method of claim 1, further comprising implanting oxygen atoms into the wafer and annealing the wafer to form a buried oxide within the wafer.

6. The method of claim 1, further comprising forming the monocrystalline semiconductor ingot by a Czochralski method.

7. A method, comprising:
forming a monocrystalline semiconductor ingot from a crystal seed having a predetermined crystal orientation;
slicing the monocrystalline semiconductor ingot to form a wafer, the wafer having a flat horizontal surface; and
marking the wafer to form an orientation indication feature at an angle greater than 0 degrees from a crystal plane that is perpendicular to the flat horizontal surface of the wafer.

8. The method of claim 7, wherein forming the monocrystalline semiconductor ingot of a semiconductor material comprises forming a monocrystalline semiconductor ingot having a face centered cubic crystal lattice.

9. The method of claim 7, wherein the face centered cubic crystal lattice is silicon.

10. A method, comprising:
providing a first semiconductor wafer having a first crystal orientation, the first wafer having an oxidized surface;
providing a second semiconductor wafer having a second crystal orientation that is different from the first crystal orientation;
bonding the second semiconductor wafer to the oxidized surface of the first wafer; and
removing a portion of the first semiconductor wafer to form a semiconductor-on-insulator wafer.

11. The method of claim 10, wherein removing a portion of the second semiconductor wafer to form a semiconductor-on-insulator wafer comprises grinding the second wafer.

12. The method of claim 10, wherein removing a portion of the second wafer comprises splitting the second wafer along the high stress region.

13. The method of claim 10, wherein providing a first semiconductor wafer having a first crystal orientation comprises providing a first crystal orientation selected from the group consisting of a [100], [110], and [111] crystal plane perpendicular to the lengthwise axis of a first ingot.

14. The method of claim 10, wherein providing a second semiconductor wafer having a second crystal orientation comprises providing a second crystal orientation selected from the group consisting of a [100], [110], and [111] crystal plane perpendicular to the lengthwise axis of a second ingot.

15. The method of claim 10, wherein providing a first semiconductor wafer having a first crystal orientation comprises providing a first crystal orientation of other than a [100], [110], and [111] crystal plane perpendicular to the lengthwise axis of a first ingot.

16. The method of claim 10, wherein providing a second semiconductor wafer having a second crystal orientation comprises providing a second crystal orientation of other than a [100], [110], and [111] crystal plane perpendicular to the lengthwise axis of a second ingot.

17. A method, comprising:
implanting a first wafer with an inert gas to form a high stress region, the first wafer having an oxidized surface, a face centered cubic crystal lattice with a [100] crystal plane parallel to a flat horizontal surface, and a first notch at a [110] crystal plane that is perpendicular to the [100] crystal plane;
providing a second wafer having a face centered cubic crystal lattice with a [100] crystal plane parallel to a flat horizontal surface, the second wafer having a second notch at a 45 degree angle to a [110] crystal plane that is perpendicular to the [100] crystal plane;
bonding the second wafer to the oxidized surface of the first wafer such that the first notch is aligned with the second notch; and
splitting the first wafer along the high stress region to form a silicon-on-insulator wafer.

18. The method of claim 17, wherein the first wafer is silicon.

19. The method of claim 17, wherein the second wafer is silicon.

20. A method, comprising:
modifying device performance on a semiconductor wafer by forming the semiconductor wafer to have a non-standard crystal orientation.

21. The method of claim 20, further comprising modifying the performance of the semiconductor wafer that is part of a semiconductor-on-insulator substrate.

22. The method of claim 20, wherein modifying device performance comprises increasing electron mobility within a transistor channel.

23. A wafer, comprising:
a first monocrystalline semiconductor layer having a first crystal orientation;
an oxide layer over the first monocrystalline semiconductor layer; and
a second monocrystalline semiconductor layer over the oxide layer, the second crystal orientation different from the first crystal orientation.

24. The wafer of claim 23, wherein the first crystal orientation is selected from the group consisting of a [100], [110], or [111] crystal plane parallel to a flat horizontal surface of the wafer.

25. The wafer of claim 23, wherein the first crystal orientation is not a [100], [110], or [111] crystal plane parallel to a flat horizontal surface of the wafer.

26. The wafer of claim 23, wherein the second crystal orientation is selected from the group consisting of a [100], [110], or [111] crystal plane parallel to a flat horizontal surface of the wafer.

27. The wafer of claim 23, wherein the second crystal orientation is not a [100], [110], or [111] crystal plane parallel to a flat horizontal surface of the wafer.

28. A wafer, comprising:
a substrate having a face centered cubic crystal lattice and a horizontal crystal plane of the lattice that is not a [100], [110], or [111] crystal plane.

29. The wafer of claim 28, further comprising a buried insulator layer.

30. The wafer of claim 28, wherein the substrate is silicon.
